(19) United States
(12) Patent Application Publication
(10) Pub. No.: US 2017/0207557 A1
(43) Pub. Date: Jul. 20, 2017

(54) SPRING SHEET

(71) Applicants: LE HOLDINGS (BEIJING) CO., LTD., Beijing (CN); LEMOBILE INFORMATION TECHNOLOGY (BEIJING) CO., LTD., Beijing (CN)

(72) Inventors: Xiangxin HUANG, Beijing (CN); Dan YU, Beijing (CN)

(21) Appl. No.: 15/242,015

(22) Filed: Aug. 19, 2016

Related U.S. Application Data
(63) Continuation of application No. PCT/CN2016/088164, filed on Jul. 1, 2016.

(30) Foreign Application Priority Data
Jan. 19, 2016 (CN) 201620051771.8

(51) Int. Cl. H01R 12/57; H05K 1/02; H01R 13/24; H05K 9/00

(52) U.S. Cl. CPC H01R 12/57; H05K 9/0064; H05K 1/023; H01R 13/2407

(57) ABSTRACT

The present disclosure relates to a spring sheet, which includes a first spring foot, a second spring foot and a soldering part; the first spring foot includes a first elastic wall and a first hook; the second spring foot includes a second elastic wall and a second hook; the first spring foot and/or the second spring foot are/is connected with the soldering part, and bend/bends and extend/extends outward relative to the soldering part. By the present disclosure, the grounding stability of the spring sheet may be reinforced, and it may be realized that two components in an electronic device are grounded simultaneously.

### CROSS-REFERENCE TO RELATED APPLICATION

This application is a continuation of International PCT Patent Application No. PCT/CN2016/088164, filed Jul. 1, 2016 (attached hereto as an appendix), and claims benefit/priority of Chinese patent application entitled “Spring Sheet”, application number 201620051771.8, filed with the State Intellectual Property Office of China on Jan. 19, 2016, which are all incorporated herein by reference in entirety.

### TECHNICAL FIELD

The present disclosure relates to the field of electronic technologies, and in particular, to a spring sheet.

### BACKGROUND

With the unintermittent development of electronic technologies, electronic devices have become indispensable tools in people's life. Because the electromagnetic radiation generated by electronic devices severely influences the quality of communication and the safety and health of human body, it requires to reduce the electromagnetic radiation amount of electronic devices and to prevent static electricity. The above requirements may be met by grounding a metal piece in an electronic device via adding a spring sheet.

In the prior art, a spring sheet is often grounded via a single contact. In some cases in which an electronic circuit cannot be turned on due to poor surface contact effect or the detaching of a spring sheet from a contact caused by external vibration, the grounding effect is poor, the functional stability of an electronic product is influenced, and the requirements of reducing electromagnetic radiation amount and preventing static electricity cannot be met.

### SUMMARY

Therefore, it is an object of the present disclosure to provide a spring sheet, thereby solving the technical problem mentioned above.

In order to attain the above object, the present disclosure provides the following solutions:

According to the first aspect of the embodiments of the present disclosure, there provides a spring sheet, which includes a first spring foot, a second spring foot and a soldering part;

the first spring foot includes a first elastic wall and a first hook;

the second spring foot includes a second elastic wall and a second hook;

the first spring foot and/or the second spring foot are/is connected with the soldering part, and bend/bends and extend/extends outward relative to the soldering part.

Optionally, the first spring foot is formed by bending and extending one end of a U-shaped soldering plate outward and then bending it inward into an arc; the second spring foot is formed by bending and extending the other end of the U-shaped soldering plate outward and then bending it inward into an arc.

Optionally, the first hook is located at an end of the first spring foot and has a convex structure; and the first elastic wall is located between the convex structure and a heel of the first spring foot.

Optionally, the second hook is located at an end of the second spring foot and has a concave structure; and the second elastic wall is located between the concave structure and a heel of the second spring foot.

Optionally, the first hook is a convex circular arc of 180 degrees.

Optionally, the second hook is a concave circular arc of an obtuse angle.

Optionally, the first spring foot and/or the second spring foot are/is configured for grounding.

Optionally, the direction in which the first spring foot bends and extends outward is opposite to the direction in which the second spring foot bends and extends outward.

Optionally, the spring sheet is connected to a printed circuit board via surface mounting.

Optionally, when the spring sheet is applied to an electronic device, the first spring foot is pressed upwardly on a first region of the electronic device, the second spring foot is pressed downwardly on a second region of the electronic device, and the soldering part is connected with a grounding component.

The spring sheet according to the present disclosure includes a first spring foot, a second spring foot and a soldering part; the first spring foot and/or the second spring foot are/is connected with the soldering part, and bend/bends and extend/extends outward relative to the soldering part. The grounding stability of the spring sheet may be reinforced, and it may be realized that two components in an electronic device are grounded simultaneously.

According to the second aspect of the embodiments of the present disclosure, there further provides a terminal, which includes the spring sheet according to each of the above embodiments.

However, when any product of the present disclosure is implemented, it does not require to attain all the above advantages simultaneously.

It should be understood that, the above general description and the following detailed description are exemplary and illustrative only, without limiting the present disclosure.

### BRIEF DESCRIPTION OF THE DRAWINGS

The drawings here are incorporated in the specification and constitute a part of the specification. The drawings illustrate some embodiments that conform to the present disclosure, and are used for explaining the principles of the present disclosure together with the specification.

In order to more clearly illustrate the technical solutions of the embodiments of the present disclosure or of the prior art, the drawings needed in the description of the embodiments or the prior art will be briefly introduced below. Apparently, according to these drawings, one of ordinary skills in the art may also obtain other drawings without creative work.

FIG. 1 is a schematic diagram of a spring sheet according to an embodiment of the present disclosure;

FIG. 2 is a schematic diagram showing a mounting of the spring sheet according to the embodiment of the present disclosure.

### DETAILED DESCRIPTION

Exemplary embodiments of the present disclosure will be illustrated in detail here, the examples of which are shown in the drawings. In order to make the objects, characteristics and advantage of the present disclosure more apparent and easier to be understood, the technical solutions in the embodiments of the present disclosure will be described below in conjunction with the drawings in the embodiments of the present disclosure. Apparently, the embodiments described are only a part of the embodiments of the present disclosure, rather than being the whole embodiments. All the other embodiments obtained by one of ordinary skills in the art based on the embodiments of the present disclosure without creative work pertain to the protection scope of the present disclosure.

The technical solutions of the present disclosure will be further described in detail below via the drawings and the embodiments.

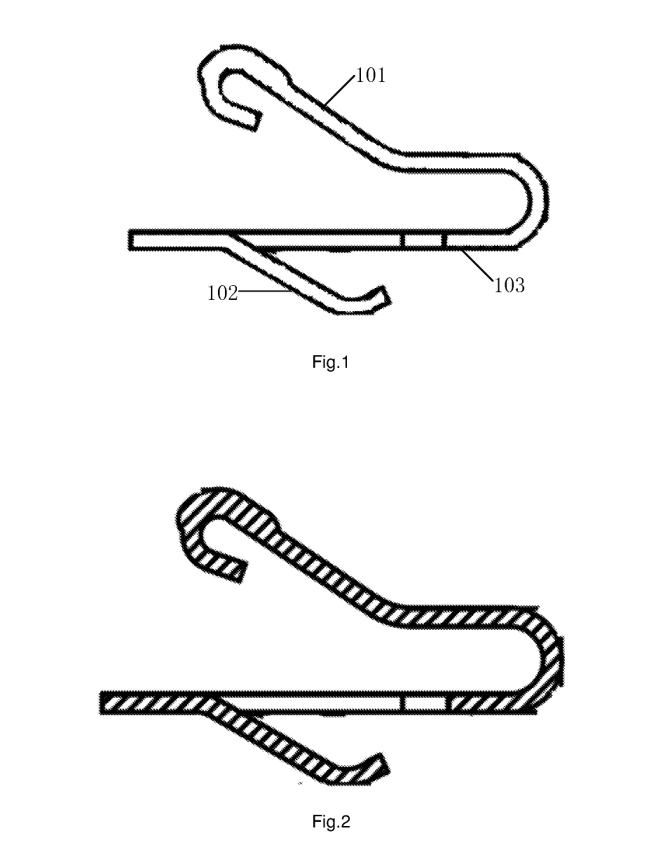

Referring to FIG. 1, a spring sheet according to the present disclosure includes a first spring foot 101, a second spring foot 102 and a soldering part 103; the first spring foot 101 includes a first elastic wall and a first hook; the second spring foot 102 includes a second elastic wall and a second hook; the first spring foot 101 and/or the second spring foot 102 are/is connected with the soldering part 103, and bend/bends and extend/extends outward relative to soldering part 103.

In an embodiment of the present disclosure, the soldering part may have a shape well-known in the art, for example, a strip, a U shape, a V shape or a combination thereof. The soldering part in FIG. 1 has a shape of a strip. The spring sheet may be formed by connecting the first spring foot and the second spring foot with the soldering part via soldering, or it may be formed by integral shaping, or it may be formed by bending.

In the embodiment of the present disclosure, the spring sheet may be applied to an electronic device, wherein the spring sheet may be horizontally placed in the electronic device, the first spring foot may be pressed upwardly on a first region of the electronic device, the second spring foot may be pressed downwardly on a second region of the electronic device, and the soldering part may be connected with a component to be grounded. Wherein, the first region and the second region are regions in the electronic device that tend to generate/receive electromagnetic radiation and/or static electricity, or regions in the electronic device that need to be prevented from electromagnetic radiation and/or static electricity, for example, the first region is a core chip (for example, System on Chip (SoC)) region, and the second region is a metal case; or the first region is a touch screen, and the second region is a core chip region; or the first region is a mainboard, and the second region is an antenna region, or any combination of each of the above regions, etc. The selection of the first region and the second region should not be regarded as a limitation to the specific implementation of the present disclosure. By pressing the first spring foot and the second spring foot, which are connected with the soldering part, on the electronic device simultaneously and bending and extending both the first spring foot and the second spring foot outward, the first hook and the second hook are respectively made to tightly contact the electronic device due to the structure and elasticity of the first elastic wall and the second elastic wall, thus the grounding stability of the spring sheet may be reinforced, and it may be realized that two components in the electronic device are grounded simultaneously.

The above electronic device includes mobile terminal device and electronic consumption product, and the mobile terminal device may be a mobile phone, a notebook computer, a tablet computer, an MP4 player or a vehicle mounted computer.

Optionally, the first spring foot is formed by bending and extending one end of a U-shaped soldering plate outward and then bending it inward into an arc; the second spring foot is formed by bending and extending the other end of the U-shaped soldering plate outward and then bending it inward into an arc.

The spring sheet may have an integrally molded structure, and it may be made by stamping and folding a soldering sheet material with good electrical conductivity.

Optionally, in the embodiment of the present disclosure, the first hook is located at an end of the first spring foot and has a convex structure; the first elastic wall is located between the convex structure and a heel of the first spring foot.

Optionally, in the embodiment of the present disclosure, the second hook is located at an end of the second spring foot and has a concave structure; the second elastic wall is located between the concave structure and a heel of the second spring foot.

Optionally, in the embodiment of the present disclosure, the first hook is a convex circular arc of 180 degrees.

Optionally, in the embodiment of the present disclosure, the second hook is a concave circular arc of an obtuse angle.

Optionally, in the embodiment of the present disclosure, the first spring foot and/or the second spring foot are/is configured for grounding.

Optionally, referring to FIG. 2, in the embodiment of the present disclosure, the spring sheet may be connected to a printed circuit board via surface mounting. The shaded portions in FIG. 2 are the two spring feet. The soldering part in FIG. 2 is connected to the printed circuit board via surface mounting, wherein the surface mounting may be soldering.

The spring sheet according to the present disclosure includes a first spring foot, a second spring foot and a soldering part; the first spring foot and/or the second spring foot are/is connected with the soldering part, and bend/bends and extend/extends outward relative to the soldering part. The grounding stability of the spring sheet may be reinforced, and it may be realized that two components in an electronic device are grounded simultaneously.

In another embodiment of the present disclosure, there further provides a terminal, which includes the spring sheet according to each of the above embodiments.

It may be further understood by one of ordinary skills in the art that, in conjunction with the units and arithmetic steps of each example described in the embodiments disclosed herein, the present disclosure can be implemented by electronic hardware, computer software or a combination thereof. In order to more clearly illustrate the interchangeability between hardware and software, the compositions and steps of each example have been generally described in the above illustration according to the functions thereof. It depends on the specific application of the technical solutions and the design constraints whether these functions are performed by hardware or software. For each specific application, one skilled in the art may realize the function described in different ways, which should not be regarded as exceeding the scope of the present disclosure.

The objects, technical solutions and beneficial effects of the present disclosure have been further illustrated in detail in the above specific implementation modes. It should be understood that, the above description only shows some specific implementation modes of the present disclosure, rather than limiting the protection scope of the present disclosure. All modifications, equivalent substitutions and improvements made within the spirits and principles of the present disclosure should be construed as falling into the protection scope of the present disclosure.

1. A spring sheet, comprising:
a first spring foot,
a second spring foot, and
a soldering part;
wherein the first spring foot comprises a first elastic wall and a first hook;
wherein the second spring foot comprises a second elastic wall and a second hook; and
wherein at least one of the first spring foot or the second spring foot is connected with the soldering part, and bends and extends outward relative to the soldering part.

2. The spring sheet according to claim 1, wherein the first spring foot is formed by bending and extending one end of a U-shaped soldering plate outward and then bending it inward into an arc; and
wherein the second spring foot is formed by bending and extending the other end of the U-shaped soldering plate outward and then bending it inward into an arc.

3. The spring sheet according to claim 1, wherein the first hook is located at an end of the first spring foot and has a convex structure; and
wherein the first elastic wall is located between the convex structure and a heel of the first spring foot.

4. The spring sheet according to claim 1, wherein the second hook is located at an end of the second spring foot and has a concave structure; and
wherein the second elastic wall is located between the concave structure and a heel of the second spring foot.

5. The spring sheet according to claim 1, wherein the first hook is a convex circular arc of 180 degrees.

6. The spring sheet according to claim 1, wherein the second hook is a concave circular arc of an obtuse angle.

7. The spring sheet according to claim 1, wherein the first spring foot and/or the second spring foot are/is configured for grounding.

8. The spring sheet according to claim 1, wherein the direction in which the first spring foot bends and extends outward is opposite to the direction in which the second spring foot bends and extends outward.

9. The spring sheet according to claim 1, wherein the spring sheet is connected to a printed circuit board via surface mounting.

10. The spring sheet according to claim 1, wherein when the spring sheet is applied to an electronic device, the first spring foot is pressed upwardly on a first region of the electronic device, the second spring foot is pressed downwardly on a second region of the electronic device, and the soldering part is connected with a grounding component.

11. A terminal, comprising:
a spring sheet, the spring sheet comprising a first spring foot, a second spring foot and a soldering part;
wherein the first spring foot comprises a first elastic wall and a first hook;
wherein the second spring foot comprises a second elastic wall and a second hook; and
wherein the first spring foot and/or the second spring foot are/is connected with the soldering part, and bend/bends and extend/extends outward relative to the soldering part.

12. The terminal according to claim 11, wherein the first spring foot is formed by bending and extending one end of a U-shaped soldering plate outward and then bending it inward into an arc; and
wherein the second spring foot is formed by bending and extending the other end of the U-shaped soldering plate outward and then bending it inward into an arc.

13. The terminal according to claim 11, wherein the first hook is located at an end of the first spring foot and has a convex structure; and
wherein the first elastic wall is located between the convex structure and a heel of the first spring foot.

14. The terminal according to claim 11, wherein the second hook is located at an end of the second spring foot and has a concave structure; and
wherein the second elastic wall is located between the concave structure and a heel of the second spring foot.

15. The terminal according to claim 11, wherein the first hook is a convex circular arc of 180 degrees.

16. The terminal according to claim 11, wherein the second hook is a concave circular arc of an obtuse angle.

17. The terminal according to claim 11, wherein the first spring foot and/or the second spring foot are/is configured for grounding.

18. The terminal according to claim 11, wherein the direction in which the first spring foot bends and extends outward is opposite to the direction in which the second spring foot bends and extends outward.

19. The terminal according to claim 11, wherein the spring sheet is connected to a printed circuit board via surface mounting.

20. The terminal according to claim 11, wherein when the spring sheet is applied to an electronic device, the first spring foot is pressed upwardly on a first region of the electronic device, the second spring foot is pressed downwardly on a second region of the electronic device, and the soldering part is connected with a grounding component.
